(19) United States
(12) Patent Application Publication
(10) Pub. No.: US 2003/0143472 A1
(43) Pub. Date: Jul. 31, 2003

(54) Manufacturing method of photomask

(76) Inventors: Yasuhiro Koizumi, Tokyo-to (JP); Shiho Sasaki, Tokyo-to (JP); Akiko Fujii, Tokyo-to (JP); Morihisa Hoga, Tokyo-to (JP); Norio Hasegawa, Hinode (JP); Katsuya Hayano, Akishima (JP)

Correspondence Address: LADAS & PARRY, 224 SOUTH MICHIGAN AVENUE, SUITE 1200, CHICAGO, IL, 60604, US

(21) Appl. No.: 10/349,590

(22) Filed: Jan. 23, 2003

(30) Foreign Application Priority Data
Jan. 24, 2002 (JP) 2002-015607

(51) Int. Cl. G03F 9/00

(52) U.S. Cl. 430/5

(57) ABSTRACT

It is an object of the present invention to provide manufacturing method of a photomask, the method enabling the provision of a resist pattern photomask which is free from the sticking of foreign matter and has high quality. The manufacturing method of a photomask comprises applying a photoresist directly to a substrate and patterning the photoresist to produce a photomask with a resist pattern, the method further comprising a process of attaching a pellicle to the substrate before inspection processs after forming the resist pattern by carrying out a process of applying the resist to the substrate, an exposure/drawing process and a developing process.

### BACKGROUND OF THE INVENTION

1. Field of the Invention

The present invention relates to a manufacturing method of a photomask. To state in detail, the present invention relates to a manufacturing method of a resist pattern photomask, the photomask being free from the sticking of foreign matter and having high quality.

2. Description of the Related Art

Photomasks used for manufacturing LSIs, LCDs, PWBs and the like have been manufactured in the following manner. A thin film of a metal such as chromium is deposited on a transparent substrate such as glass to form a light-shielding film and a photoresist sensitive to light or electron beam energy is applied to the this light-shielding film. A mask pattern data is drawn on the photoresist by using a light or electron beam drawing device by exposure based on the design data of a semiconductor device. Thereafter, the photoresist is developed to form a resist pattern and in succession, the light-shielding film is patterned using the resist pattern as a mask by wet or dry etching to finally form a hard mask made of a metal pattern (light-shielding film), thereby manufacturing a photomask. Then, the resist film is peeled off and the hard mask is cleaned. Then, the hard mask is subjected to inspections of dimensions, positional accuracy and outside appearance and to repairing of defects, followed by final cleaning, then equipped with a pellicle and supplied to users through a final inspection.

For this, a relatively long period of time is required to carry out a process of manufacturing a mask and the resulting mask is therefore expensive.

A light source for a wafer exposure apparatus used to transfer an expected pattern of a photomask (reticle) as mentioned above to a wafer is shifted to those having shorter wavelengths, in a short time, to cope with the micronization of patterns such as LSIs. The wavelength for exposure is changed from a g-line (436 nm) to an i-line (365 nm). Further, an excimer laser such as KrF (248 nm) and, hereafter, an excimer laser such as ArF (193 nm) are coming into use.

Only for the purpose of evaluating the performance characteristics of a developed semiconductor device, it is considered that the purpose of evaluating the characteristics can be attained even if a light-shielding type resist material as mentioned above which does not transmit exposure light having short wavelengths is used and applied the above light-shielding type resist directly to a transparent substrate, followed by patterning to produce a photomask of a light-shielding resist pattern (hereinafter referred to as “light-shielding resist pattern photomask”) and the resulting photomask is supplied for to the transfer of a pattern to a wafer after it is completed through a simple inspection of foreign matter and measurement of dimensions.

In addition, in Japanese Patent Application Laid-Open (JP-A) No. 5-289307, a reticle obtained by using a photoresist and forming a resist pattern directly on a substrate is proposed in the above manner.

However, in the case of producing such a light-shielding resist pattern photomask, it is fairly possible to give rise to the problems that (1) it is substantially impossible to clean off the foreign matter stuck in the process of the inspection of dimensions and outside appearance after a drawing process and a developing process(because a photoresist having less durability to cleaning physically and chemically is used), and also (2) when applying a resist by a spin coater or the like, the resist stuck to the sides, backside and periphery of the surface of a substrate is peeled off when the substrate is inserted into a cassette used during pattern drawing, when the substrate is brought into contact with a conductive contact probe and also when the substrate is conveyed in a developing device, with the result that the peeled resist is eventually stuck to the pattern-formed portion.

### SUMMARY OF THE INVENTION

Therefore, an object of the present invention is to provide a manufacturing method of a photomask, the method enabling the provision of a light-shielding resist pattern photomask which is free from the sticking of foreign matter and has high quality in a high yield.

Another object of the present invention is to provide a manufacturing method of a photomask which can manufacture a photomask at a low cost in a short period of time.

The above object can be attained by a manufacturing method of a photomask comprising; applying a light-shielding type resist directly to a transparent substrate and patterning the light-shielding type resist to produce a photomask with a light-shielding resist pattern; and a process of attaching a pellicle to the substrate before an inspection process after forming the light-shielding resist pattern, by applying light-shielding type resist and carrying out an exposure/drawing process and a developing process.

By the attachment of the pellicle on the light-shielding resist pattern immediately after carrying out exposure/drawing and developing processes ensures that because the surface of the light-shielding resist pattern photomask is protected by the pellicle, there is no fear as to the sticking of foreign matter on the light-shielding resist pattern in the subsequent inspection process processes such as dimensional inspection and outside appearance inspection and therefore a light-shielding resist pattern photomask which is free from any defect and has high quality can be provided.

The above object can also be attained by the provision of a manufacturing method of a photomask, the method comprising applying a light-shielding type resist directly to a transparent substrate and patterning the photoresist to produce a photomask with a light-shielding resist pattern, the method further comprising a process of attaching a temporary pellicle to the substrate before an inspection process after forming the light-shielding resist pattern by applying light-shielding type resist, carrying out an exposure/drawing process and a developing process and a process of applying a real pellicle in place of the temporary pellicle to the photomask which has passed through the subsequent inspection process and passed the inspection.

In this case, also there is no fear as to the sticking of foreign matter on the resist pattern in the inspection processes such as processes of inspecting dimensions and outside appearance and therefore a light-shielding resist pattern photomask which has high quality can be provided in a high yield. Further, it is not required to use a highly expensive pellicle in a product which has not passed inspection and therefore the manufacturing cost can be lowered.

The above object can also be attained by the provision of a manufacturing method of a photomask, the method comprising applying a light-shielding type resist directly to a substrate and patterning the photoresist to produce a photomask with a light-shielding resist pattern in the basic process shown in FIG. 5, wherein a series of processes involving a process applying the resist, an exposure/drawing process, a developing process, an inspection process, a process of attaching a pellicle and a final inspection process are carried out in a closed treating system.

In the method of the present invention wherein the pellicle or the temporary pellicle is attached prior to the inspection process as aforementioned, it is also desirable to carry out the series of processes from the process of applying the resist to the inspection process in a closed treating system.

In the present invention, all processes for the production of a light-shielding resist pattern photomask is carried out in a closed system in this manner, therefore, the sticking of foreign matter caused by the photomask being carried out of the system can be reduced, and improvements in quality and in yield of the products can be expected.

Moreover, the present invention made to attain the above object resides in a manufacturing method of a photomask, the method comprising applying a light-shielding type resist directly to a substrate and patterning the photoresist to produce a photomask with a light-shielding resist pattern, the method further comprising a process of cleaning and removing the resist stuck to the sides, backside and periphery of the surface of the substrate when or after applying the light-shielding type resist to the substrate before an exposure/drawing process and a developing process are carried out, to form a light-shielding resist pattern.

Also, in the method of the present invention in which the pellicle or the temporary pellicle is attached before the inspection process, or in the method of the present invention in which the series of processes are carried out in a closed system, as mentioned, the exposure/drawing process and the developing process are preferably carried out to form the resist pattern by using the substrate from which the resist stuck to the sides, backside and periphery of the surface of the substrate when or after the light-shielding type resist is applied to the substrate is removed as well.

This solves the problem that the resist stuck to the sides and backside of the substrate when applying the resist is peeled off, for example, during drawing or when the substrate is conveyed in a developing device and is stuck to the pattern-formed portion as foreign matter.

As mentioned above, according to the present invention, the quality of a mask can be ensured by attaching a pellicle immediately after a drawing process and a developing process and by manufacturing the mask in a continuous automatized line, though the sticking of foreign matter must be avoided to the utmost because it is difficult to clean away these foreign matter physically or chemically in the manufacturing of a resist pattern photomask. Also, because the resolution of a part of a pattern can be improved, the feedback of the evaluation of characteristics and circuit design can be made quickly, so the TATs can be developed and a mask can also be supplied at low costs by introducing a light-shielding resist pattern photomask obtained by the manufacturing method of the present invention into a debug of device design in the development of high-technology semiconductor devices such as logic, microcomputer, SRAMs and DRAMs. Also, the photomask made of a resist pattern is expected to obtain the effect of reducing costs and to contribute to environmental safeguard because the photomask with a defect, or which have been used are regenerated by peeling a pellicle to regenerate a substrate, which makes it possible to reuse the substrate material.

### BRIEF DESCRIPTION OF THE DRAWINGS

FIG. 1 is a typical flow diagram in one embodiment of a manufacturing method according to a first embodiment of the present invention.

FIG. 2 is a typical flow diagram in one embodiment of a manufacturing method according to a first embodiment and an eighth embodiment of the present invention.

FIG. 3 is a typical flow diagram in one embodiment of a manufacturing method according to a third embodiment of the present invention.

FIG. 4 is a typical flow diagram in one embodiment of a manufacturing method according to a fifth embodiment and a sixth embodiment of the present invention.

FIG. 5 is a typical flow diagram in one embodiment of a basic manufacturing method according to a first embodiment of the present invention.

FIG. 6 is a typical view of the structure of a mask in one embodiment of a manufacturing method according to a seventh embodiment of the present invention, wherein (a) is a structural view of the cross section and (b) is a front view.

FIG. 7 is a typical view of the structure of a mask in one embodiment of a manufacturing method according to a ninth embodiment of the present invention, wherein (a) is a structural view of the cross section and (b) is a front view.

FIG. 8 is a typical view of the structure of a mask in one embodiment of a manufacturing method according to a tenth embodiment of the present invention.

FIG. 9 is a typical flow diagram of essential processes in one embodiment of a manufacturing method according to a fourth embodiment of the present invention.

### DESCRIPTION OF THE PREFERRED EMBODIMENT

The present invention will be explained in detail based on an embodiment shown in the drawing, taking as an example, the case of a photomask (reticle) as a master plate used to transfer a predetermined integrated circuit pattern to a wafer in an exposure process of a process of manufacturing a semiconductor integrated circuit.

Attachment of a Pellicle Prior to Inspection

A photoresist material having light-shielding ability to light with a wafer exposure wavelength is hereinafter called a light-shielding type resist. Also, a resist pattern photomask formed using the resist is called a light-shielding resist pattern photomask or a light-shielding resist pattern.

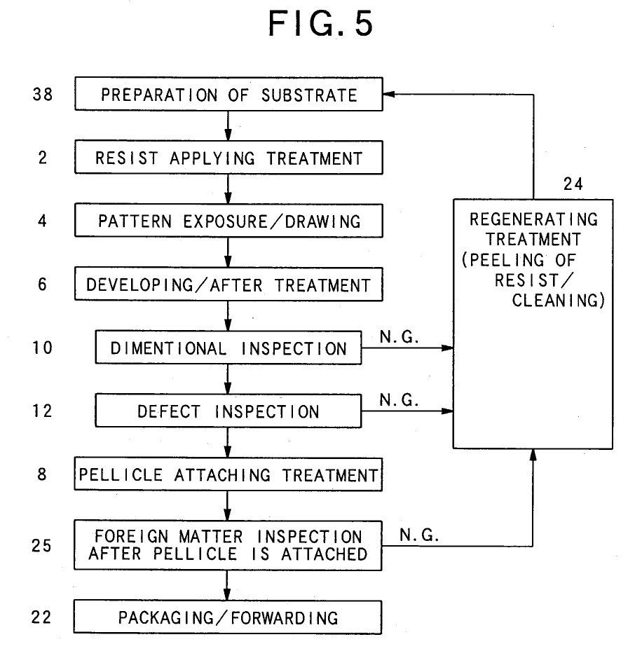

A basic process for the production of the light-shielding resist pattern photomask involves, as shown in FIG. 5, a process 38 of preparing a substrate, a process 2 of applying a light-shielding type resist, then a process 4 of performing pattern exposure and a process 6 of performing developing and after-treatment to form a light-shielding resist pattern 7 on a transparent substrate 1. Thereafter, inspection processs involving a dimensional inspection process 10 and a defect inspection process 12 are carried out to confirm whether the product is a non-defective or not. If the product is confirmed to be a non-defective, it passes through a pellicle-attaching process 8 to attach a pellicle 9, treated in a process 25 of inspecting foreign matter after the pellicle is attached. The mask which passes the inspection is forwarded through a packaging/forwarding process 22. On the other hand, the mask which does not pass any of the dimensional inspection process 10, the defect inspection process 12 or the process 25 of inspecting foreign matter after the pellicle is attached is regenerated and used through a regenerating process 24.

In the production of a mask using these basic processes, there is the problem that the mask is judged to be defective in high possibility caused by the sticking of foreign matter in the dimensional inspection process 10 and in the defect inspection process 12.

A first embodiment of the present invention is characterized by a process of attaching a pellicle prior to an inspection process after a light-shielding type resist is applied to a substrate and an exposure/drawing process and a developing process are carried out to form a light-shielding resist pattern.

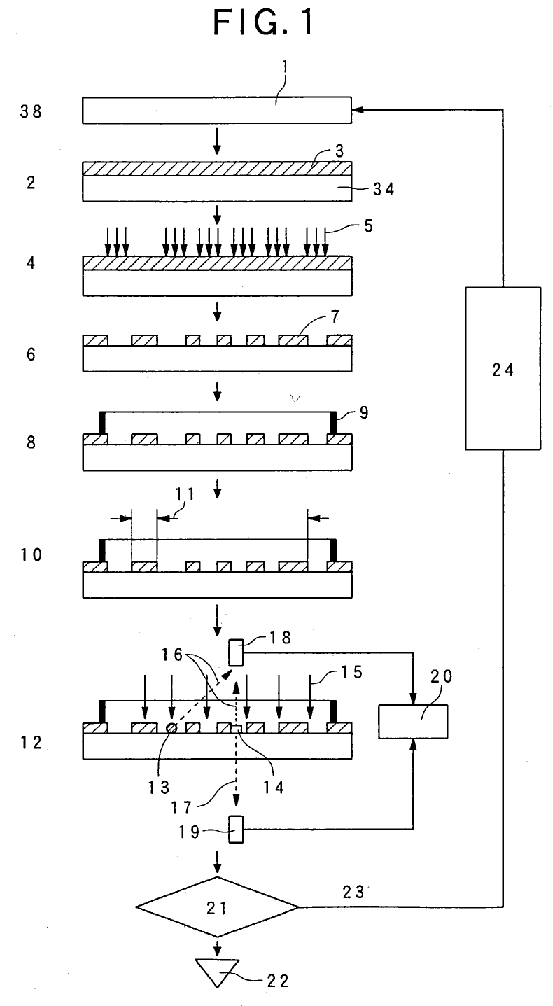

Specifically, in a manufacturing method of a light-shielding resist pattern photomask, as shown in an embodiment shown in FIG. 1, a light-shielding type resist is applied to a transparent substrate 1 in a light-shielding type resist application process 2, an electron beam 5 is irradiated to a light-shielding type resist-applied substrate 45 in a pattern exposure/drawing process 4 using an electron beam and next, developing is carried out in a developing/after-treatment process 6 to form a light-shielding resist pattern 7 for the purpose of decreasing defects in the process of producing the mask. Because the light-shielding resist pattern 7 cannot stand chemical cleaning and physical cleaning, the pellicle 9 is attached before the mask is subjected to inspection processes including the dimensional inspection process 10 and the defect inspection process 12 for the purpose of preventing the sticking of foreign matter 13 caused by process handling and the like. After that, in the dimensional inspection process 10, measurements of dimensions and positional accuracy are made using a reflecting light 16. Next, in the defect inspection process 12, a reflecting light 10 and a transmitting light 17 are taken in a decision circuit 20 through a reflecting light detector 18 and a transmission light detector 19 and stored there. After the defect inspection process 12 is finished, defects are called in as acceptance determination process 21 to determine the existence of the foreign matter 13 and resist defects 14. Then, a non-defective light-shielding resist pattern photomask is forwarded through the packaging/forwarding process 22.

In the case of the defective 23, it is subjected to the regenerating process 24 and the transparent substrate 1 is reused.

As the transparent substrate 1, a quartz glass substrate suitable for short wavelengths is usually used. The substrate 1 is not limited to these materials.

As a material used for the light-shielding type resist 3 used to deposit a light-shielding resist pattern on the substrate, materials are used which are sensitive to electron beams or light and have substantially low transmittance for light with the exposure wavelength, for example, ultraviolet light such as i-line (365 nm), KrF (248 nm) and ArF (193 nm), used in an exposure apparatus when the light-shielding resist pattern 7 of the resulting photomask is transferred to a wafer. Particularly, those having a transmittance of almost zero, namely, less than 1%, desirably less than 0.5% and practically less than 0.1% for excimer laser light such as KrF (248 nm) and ArF (193 nm) are preferable. If the light transmittance of the resist for light with the exposure wavelength used when transferring a pattern to a wafer is low in this manner, the resist forms the light-shielding portion of the formed reticle, making it possible to transfer a pattern. There is no particular limitation to a material used as the light-shielding type resist 3 as far as it has the aforementioned characteristics and either of positive types or negative types may be used. Though not limited to the below, specific examples may include; positive types such as novolac type resist, e.g., compositions of novolac resins and quinone diazides and compositions of novolac resins and polymethylpentene-1-sulfons; chemically amplified type resist obtained by compounding an inhibitor, an acid-generating agent and the like with a copolymer of α-methylstyrene and methyl α-chloroacrylate, a novolac resin or a phenol resin; negative types such as crosslinking type resist such as those using chloro-methylated polystyrene as the major component.

Although the process 2 of applying a light-shielding resist is usually carried out by spin coating, scan coating may be used besides the spin coating. After the application, a prebaking process by a hot plate system or a hot air circulating oven system may be provided according to the need. It is desirable to remove a resist, stuck to the sides, backside and periphery of the surface of the substrate during spin-coating, prior to the prebaking process as will be explained later.

The developing/after-treatment process 6 may be carried out by any method such as a dipping method, spraying method or paddle method using an aqueous alkali solution and an organic solvent depending on the type of resist to be used. However, a spraying method or a paddle method is desirable with the intention of decreasing the amount of foreign matter to be stuck and of decreasing the amount of the solution to be used. Post-baking treatment is carried out according to the need to form the light-shielding resist pattern 7.

Examples of materials used for the pellicle 9 may include nitrocellulose films, nitrocellulose films with an antireflection film such as those obtained by coating with an inorganic type thin film having a large refractive index by sputtering or by applying an organic type multilayer film, denatured cellulose films and fluorine type organic thin films. However, the pellicle 9 is not limited to these materials at all.

The dimensional inspection process 10 is not particularly limited to the above exemplified embodiment and is for measuring and inspecting the dimension and positional accuracy of a pattern. As a method of measuring dimensions, measurement by a Scatterometry method which enables measurement under atmospheric pressure in a non-contact state with high accuracy is most superb (Scatterometry method: measurements of line width, pitch, height and angle of a side wall on an irregular surface can be accomplished quickly with high accuracy under atmospheric pressure from the interference light produced by applying light from the surface) because the measurement of dimensions is made after the pellicle is attached. In addition, measurement made by detecting scatter light from an edge and dimensional measurement based on the detection of an edge by detecting a change in the strength of an optical image formed by light transmitted through a slit at the edge portion may be used. However, these measuring methods are not limited to the above.

For the measurement of a pattern position accuracy, for example, a method developed by Lica may be used in which the scatter light of an edge by reflecting light is detected to measure the coordinate by using a laser interferometer, though the method used in the present invention is not limited to this method.

The defect inspection process 12 is for inspecting the shape defects of the light-shielding resist pattern and the sticking of foreign matter. As one example (see FIG. 1), a method may be exemplified in which reflecting light and transmitting light are put with respect to a mask in the condition that the optical axis of the reflecting light coincides with the optical axis of the transmitting light at the same position on the mask as in the case of using a STAR light inspecting device manufactured by KLA-Tencor. The case where the signals of the reflecting light offsets the signals of the transmitting light is judged to be non-defective. On the other hand, in the case where there is a difference between the signals of the reflecting light and the signals of the transmitting light, the foreign matter 13 and the resist defects 14 are stored as defectives in the decision circuit 20. After the inspection is finished, these defects are called again and subjected to an acceptance determination 21, thereby, a method to judge whether the mask is a non-defective or a defective can be exemplified.

Besides the above methods, for multi layout light-shielding resist pattern photomask, there are method using a light-transmission type detector produced by KLA-Tencor, or Lasertech, and a Die-to-Die comparative inspection method by reflecting light. Other than the above, there is a method of inspecting foreign matter by irradiating laser light to detect the scatter light, but the intensive laser light may give rise to resist damages, therefore not suitable as the inspection device. Except for these devices, inspection of foreign matter by a method using a combination of transmitting light and reflecting light may also be optionally combined to carry out the inspection of foreign matter. Also, according to the need, a part of the inspections may be omitted to simplify the inspection. Also, the inspection of foreign matter can be accomplished only by the aforementioned STAR light inspection method used to carry out inspection using reflecting light and transmitting light. Also, the defect inspection methods used in the present invention are not particularly limited to these exemplified methods.

The mask which has been judged to be a defective in the dimensional inspection process 10 or in the defect inspection process 12 is subjected to the regenerating process 24 where the defective mask is regenerated.

Although no particular limitation is imposed on the regenerating process 24, a method in which the resist is chemically removed using an alkali developing solution, a heated acid, an organic solvent or the like after the pellicle is peeled off, or the resist is physically removed from the substrate by using an oxygen plasma or ozone-UV and further by performing cleaning treatment after the pellicle is peeled off, to be used as a regenerated substrate.

Attachment of a Temporary Pellicle

A second embodiment of the invention is characterized by a process of attaching a temporary pellicle 36 prior to an inspection process after a light-shielding type resist is applied to the substrate, an exposure/drawing process, a developing process and an after-treatment process are carried out to form a light-shielding resist pattern, and then attaching a real pellicle 9 in place of the temporary pellicle 36 to a photomask which has passed inspection through the inspection process.

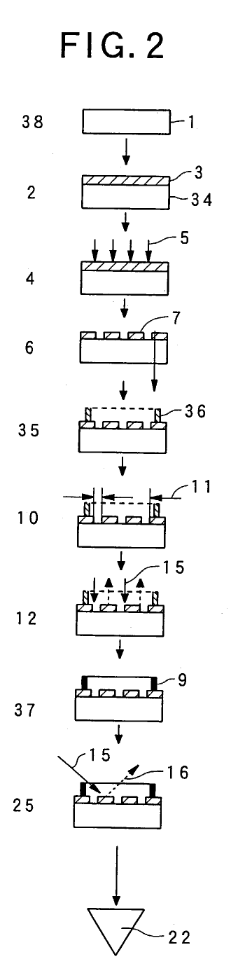

In the second embodiment of the present invention like the case of the first embodiment of the present invention, the temporary pellicle is attached immediately after the developing process and the after-treatment process are finished in the production of the light-shielding resist pattern photomask. Since the pellicle 9 is expensive, as shown in FIG. 2, the temporary pellicle 36 which is less adhesive is attached in a temporary pellicle-attaching process 35. After it is confirmed that no defect is observed in the dimensional inspection process 10 and in the defect inspection process 12, the real pellicle is attached in place of the temporary pellicle and the real pellicle is then treated in a fixing process 37. Then, the mask is subjected to a foreign matter-inspecting process 25 after the real pellicle is attached, to confirm that the no defect is observed and then forwarded in the packaging/forwarding process 22.

As the temporary pellicle 36, any material may be used without any particular limitation as far as it is basically cheaper than the real pellicle, can protect the surface of the resist pattern temporarily and can be peeled off afterwards with ease. The temporary pellicle is attached using an adhesive which does not adversely affect the photoresist.

In an eighth embodiment of the present invention, as shown in FIG. 2, a temporary pellicle 36 has the same quality as the real pellicle 9. A photocuring agent is used as an adhesive or a temporary pellicle 36 using a photocuring agent is used. The temporary pellicle 36 is attached at ambient temperature or in a normal condition, not cured, the pellicle is temporarily applied by low adhesion. After the inspection process is finished, the foregoing adhesive is melted and cured by heating or irradiating light to fix the pellicle in the case of a non-defective.

About other points of view, they are the same as those explained in the first embodiment of the present invention.

Removal of a Resist on the Surface to Which a Pellicle is Attached

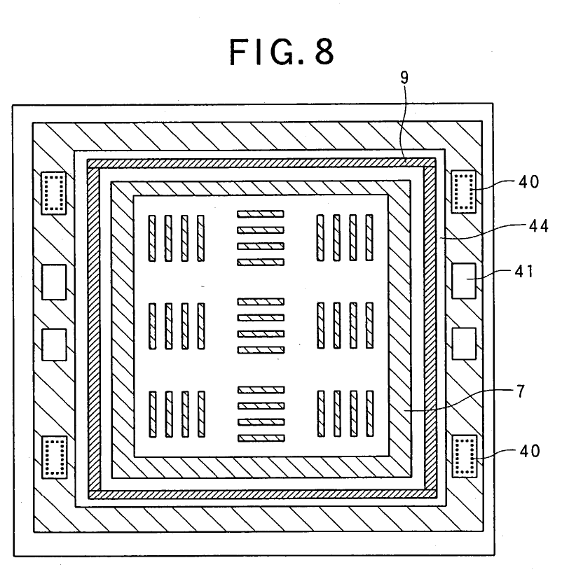

In a tenth embodiment of the present invention, as shown in FIG. 8, a resist removing section 44 in the area to which a pellicle adheres, an exposure apparatus-adsorbing section 40 and an exposure apparatus alignment cell section 41 are drawn and a resist is removed when a resist pattern is exposed to light, to prevent the resist pattern from being affected by the peeling of a temporary pellicle 36, by the generation of foreign matter as an exposure apparatus-adsorbing section 40 and an exposure apparatus alignment cell section 41 are rubbed when a real pellicle 9 is attached or when a wafer is exposed to light.

Production in a Cleaned Treating System

A third embodiment of the present invention is characterized by a method in which a series of processes involving a process of applying a resist to a substrate, an exposure/drawing process, a developing process, an inspection process, a pellicle-attaching process and a final inspection process are carried out in a closed treating system.

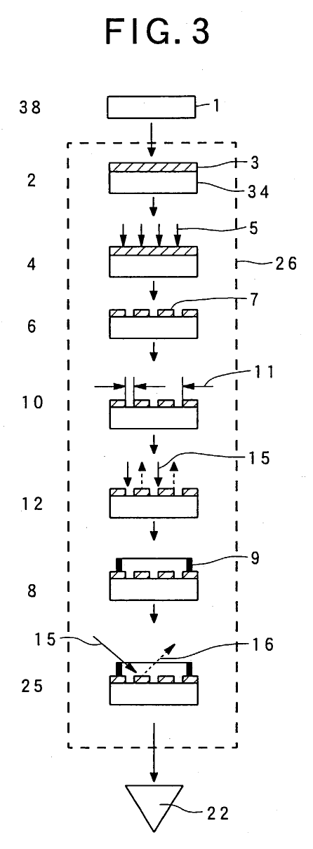

In the manufacturing of a resist pattern photomask, as shown in FIG. 3, processes involving a process 2 of applying a light-shielding resist to a transparent substrate 1, a pattern exposure/drawing process 4 using an electron beam 5, a developing/after-treatment process 6, a dimensional inspection process 10, a defect inspection process 12, a pellicle-attaching process 8 and a foreign matter inspection process 25 after the pellicle is attached are carried out in a closed treating system 26 to produce the photomask, thereby attempting to reduce defects caused by the sticking of foreign matter.

For example, the usage of the cleaned closed system such as a method in which these treating devices used in each process is disposed in the same clean room, and a method in which the passage for carrying the substrate between each process is made to be a continuous and closed passage such as a clean tunnel can be mentioned. In this case, it is also desired to carry out each treatment by either automatic or remote control.

It is to be noted that in the aforementioned first, second and eighth embodiments though not illustrated, it is also desirable to carry out such a series of processes from the process of applying a resist to the substrate to the final inspection process in a closed treating system.

Continuous Treating System

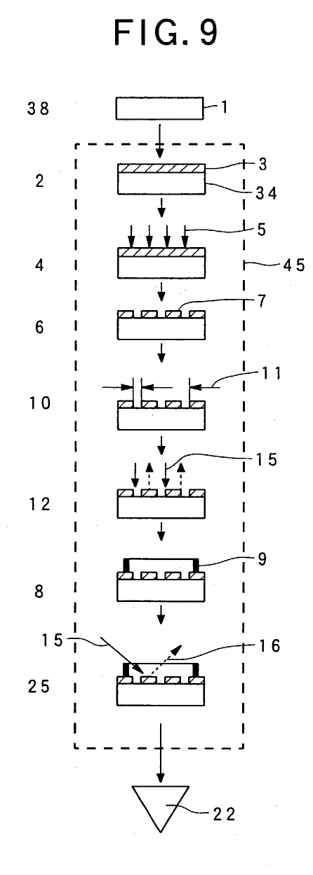

In a fourth embodiment of the present invention, for example, a production process as aforementioned as one unit which is perfectly automatized is treated in a closed continuous system 45 as shown in FIG. 9, to thereby decrease defects caused by the sticking of foreign matter.

It is to be noted that in the aforementioned first, second and eighth embodiments though not illustrated, it is also desirable to carry out such a series of processes from the process of applying a resist to the substrate to the final inspection process in a closed treating system.

Removal of a Resist Stuck to Portions Other Than the Surface of the Mask

A fifth embodiment and a sixth embodiment of the present invention are methods of manufacturing a photomask, each being characterized by a process in which after a light-shielding type resist is applied to a substrate, the resist stuck to the sides and backside of the substrate is cleaned and removed and then an exposure/drawing process and a developing process are carried out to form a resist pattern.

In this embodiment, a substrate 34 from which a resist stuck to the end face and backside thereof is removed is used as the resist-applied substrate used for the production of the light-shielding resist pattern photomask.

Examples of a method of applying a resist include a method of applying by a scan coating method besides a spin coating method. Because the scan coating method enables the application of a resist to a desired area, it is effective as a method of applying no resist to the peripheral end section of the drawn surface of the mask to prevent the generation of foreign matter caused by a conducting pin when drawing using electron beams.

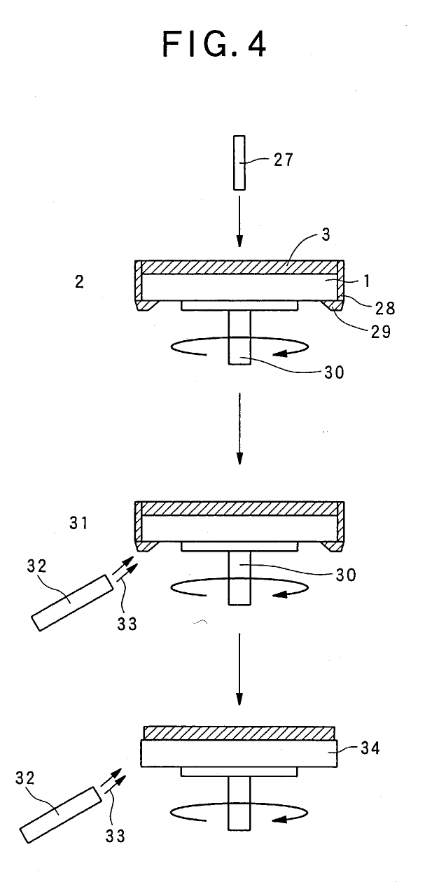

As to the removal of the resist formed by spin coating, as shown in FIG. 4, a light-shielding type resist is applied using a spinner 30 in a light-shielding resist application process 2 and then an organic type solvent 33 for removing a resist is applied to the backside and end face of the substrate by the backside and end face cleaning nozzle 32 to remove a resist 29 stuck to the backside and a resist 28 stuck to the end face, thereby forming the substrate 34 from which the resist stuck to the end face and backside of the substrate is removed.

Further, though not illustrated, a substrate free of the sticking of a resist to the front and back end faces and back face thereof is also obtained in the same manner by a method in which a resist is applied selectively only to the area where the mask is produced when the resist is applied to the substrate, for example, by a measures in which the surface periphery, the sides and backside of the substrate except for the surface on which the mask is to be produced are covered mechanically and this cover is dismounted after the resist is applied.

If a remaining resist or a resist residue are left on the end face and backside of the substrate coated already with a resist, the resist is peeled off from these positions, causing foreign matter to stick to the portion where the mask is to be formed when the mask is inserted into a drawing cassette, a conductive pin is made to be in contact with the mask when drawing using electron beams and the mask is carried in a developing process. It is therefore essential to use substrates whose end face and backside are free of the remaining resist and resist residue as the substrate with a resist to be used with the view of producing a high quality mask. Such methods as mentioned above prevent the generation of pollution and defects of the resist pattern photomask.

Manufacturing Method of a Mask Wherein a Resist Pattern is Formed on a part of a Mask Substrate Which a Light-shielding Film Other Than a Resist is Attached and Patterned

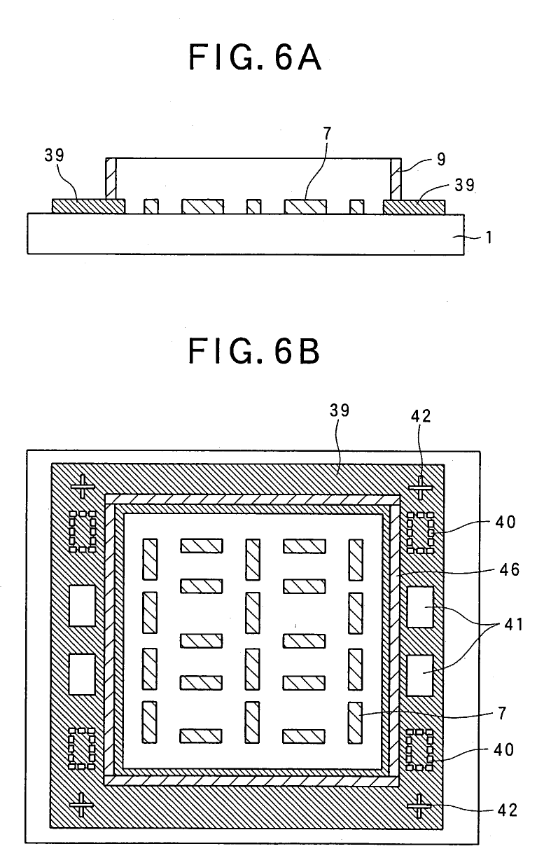

A seventh embodiment of the present invention relates to a manufacturing method of a mask, wherein as shown in FIG. 6(a) and FIG. 6(b), where a wafer exposure apparatus-adsorbing section 40, an alignment pattern section 41 and the recto section of a pellicle-attaching surface 46 are formed of not a resist but, for an example, a chromium metal thin film and a device forming section is formed using a resist pattern.

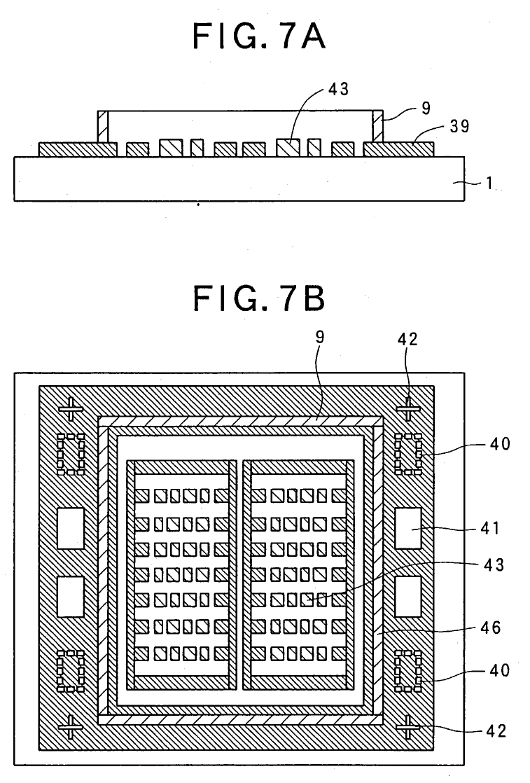

In a ninth embodiment of the present invention, as shown in FIG. 7(a) and FIG. 7(b), a part of the device pattern is also formed of not a resist but, for an example, a chromium metal thin film. Also, in order to improve the resolution of the transfer to a wafer, only for sections which needs a partial design change, a gate section for which a high rating of resolution is required on a wafer and a cell section, the resist on the light-shielding resist pattern section is applied in such thickness as to shift a phase at 180 degrees by light with a wafer exposure wavelength after the final developing process is finished, to thereby form a light-shielding resist pattern 43 provided with a phase difference. Also, as the light-shielding resist, those transmitting apart, specifically, for example, about 1% to 40% of light with an exposure wavelength are used to improve resolution.

The manufacturing method in the present invention has been explained by way of embodiments in the above. However, the present invention is not limited to these embodiments at all and various modifications and changes of the embodiments may be made.

The manufacturing method of the present invention is preferably applied to the production of logic products of semiconductor devices which are complicated in a change of mask designs and are obtained in a multikind and small-quantity production system or to the production of masks used for the evaluation of initial characteristics when developing products for microcomputers, SRAMs and DRAMs. The manufacturing method of the present invention may also be applied to the production of masks for the patterning of displays enabling non-contact exposure between the mask and products when exposing to light and to the production of masks for developments such as lead frames which are the types produced in a small-quantity.

What is claimed is:

1. A manufacturing method of a photomask, the method comprising applying a resist directly to a substrate and patterning the resist to produce a photomask with a resist pattern, the method further comprising a process of attaching a pellicle to the substrate before an inspection process after forming the resist pattern by applying the resist, carrying out an exposure/drawing process and a developing process.

2. A manufacturing method of a photomask, the method comprising applying a resist directly to a substrate and patterning the resist to produce a photomask with a resist pattern, the method further comprising a process of attaching a temporary pellicle to the substrate before an inspection process after forming the resist pattern by applying the resist, carrying out an exposure/drawing process and a developing process and a process of applying a real pellicle in place of the temporary pellicle to the photomask which has passed through the subsequent inspection process and passed the inspection.

3. A manufacturing method of a photomask, the method comprising applying a resist directly to a substrate and patterning the resist to produce a photomask with a resist pattern, wherein a series of processes involving a process applying the resist, an exposure/drawing process, a developing process, an inspection process, a process of attaching a pellicle and a final inspection process are carried out in a treating system disposed in a closed system.

4. A manufacturing method of a photomask according to claim 1, wherein a series of processes from the process of applying the resist to the inspection process are carried out in a closed and continuous treating system.

5. A manufacturing method of a photomask according to claim 2, wherein a series of processes from the process of applying the resist to the inspection process are carried out in a closed and continuous treating system.

6. A manufacturing method of a photomask, the method comprising applying a resist directly to a substrate and patterning the resist to produce a photomask with a resist pattern, wherein after the resist is applied to the substrate, an exposure/drawing process and a developing process are carried out using the substrate from which the resist stuck to the sides and backside of the substrate is removed, to form a resist pattern.

7. A manufacturing method of a photomask according to claim 1, the method comprising applying a resist directly to a substrate and patterning the resist to produce a photomask with a resist pattern, wherein after the resist is applied to the substrate, an exposure/drawing process and a developing process are carried out after the resist stuck to the sides and backside of the substrate is removed, to form a resist pattern.

8. A manufacturing method of a photomask according to claim 2, the method comprising applying a resist directly to a substrate and patterning the resist to produce a photomask with a resist pattern, wherein after the resist is applied to the substrate, an exposure/drawing process and a developing process are carried out after the resist stuck to the sides and backside of the substrate is removed, to form a resist pattern.

9. A manufacturing method of a photomask according to claim 3, the method comprising applying a resist directly to a substrate and patterning the resist to produce a photomask with a resist pattern, wherein after the resist is applied to the substrate, an exposure/drawing process and a developing process are carried out after the resist stuck to the sides and backside of the substrate is removed, to form a resist pattern.

10. A manufacturing method of a photomask according to claim 1, wherein a resist is applied to the substrate patterned with a light-shielding film other than a resist, to form a part of the pattern of the mask with a resist pattern.

11. A manufacturing method of a photomask according to claim 2, wherein a resist is applied to the substrate patterned with a light-shielding film other than a resist, to form a part of the pattern of the mask with a resist pattern.

12. A manufacturing method of a photomask according to claim 3, wherein a resist is applied to the substrate patterned with a light-shielding film other than a resist, to form a part of the pattern of the mask with a resist pattern.

13. A manufacturing method of a photomask according to claim 2, wherein a photocuring agent or a heatcuring agent is used as an adhesive for the temporary pellicle and in the case where the obtained photomask is a nondefective in the inspection process, light or heat is applied to fix it as it is.

14. A manufacturing method of a photomask according to claim 1, the method comprising applying a resist to the substrate patterned with a light-shielding film other than a resist to form a part of the pattern of the mask with a resist pattern, wherein the resist film is made to have such a thickness as to shift a phase at 180 degrees by light with a wafer exposure wavelength to improve the resolution of the transfer to a wafer, and also, a light-shielding resist transmitting a part of exposure light is applied to form a pattern.

15. A manufacturing method of a photomask according to claim 2, the method comprising applying a resist to the substrate patterned with a light-shielding film other than a resist to form a part of the pattern of the mask with a resist pattern, wherein the resist film is made to have such a thickness as to shift a phase at 180 degrees by light with a wafer exposure wavelength to improve the resolution of the transfer to a wafer, and also, a light-shielding resist transmitting a part of exposure light is applied to form a pattern.

16. A manufacturing method of a photomask according to claim 3, the method comprising applying a resist to the substrate patterned with a light-shielding film other than a resist to form a part of the pattern of the mask with a resist pattern, wherein the resist film is made to have such a thickness as to shift a phase at 180 degrees by light with a wafer exposure wavelength to improve the resolution of the transfer to a wafer, and also, a light-shielding resist transmitting a part of exposure light is applied to form a pattern.

17. A manufacturing method of a photomask according to claim 1, wherein a resist on the contact surface of a frame of a temporary pellicle or the pellicle in the resist pattern photomask is removed.

18. A manufacturing method of a photomask according to claim 2, wherein a resist on the contact surface of a frame of a temporary pellicle or the pellicle in the resist pattern photomask is removed.

19. A manufacturing method of a photomask according to claim 3, wherein a resist on the contact surface of a frame of a temporary pellicle or the pellicle in the resist pattern photomask is removed.

20. A manufacturing method of a photomask according to claim 1, wherein the resist has light shielding ability against a wafer exposing wavelength.
